(19) United States
(12) Patent Application Publication
(10) Pub. No.: US 2008/0232076 A1
(43) Pub. Date: Sep. 25, 2008

(54) Attaching/Detaching Structure Of Electronic Device

(75) Inventor: Kazuei YOSHIOKA, Tokyo (JP)

Correspondence Address: NDQ&M WATCHSTONE LLP, 1300 EYE STREET, NW, SUITE 1000 WEST TOWER, WASHINGTON, DC, 20005, US

(73) Assignees: Aruze Corp., Koto-ku (JP); Seta Corp., Koto-ku (JP)

(21) Appl. No.: 12/052,072

(22) Filed: Mar. 20, 2008

(30) Foreign Application Priority Data
Mar. 22, 2007 (JP) JP2007-073956

(51) Int. Cl. H05K 1/14

(52) U.S. Cl. 361/803

(57) ABSTRACT

The invention comprises a unit part 3 that is attachable/detachable to/from a frame 100; and an engagement device that enables the unit part 3 to be attachable/detachable to/from the frame 100 and comprises; an engagement pin 90 diposed at one of the frame 100 and the unit part 3; and an engagement member 51 disposed at the other of the frame and the unit part, having a recess engaged with the engagement pin 90. The engagement member 51 is pivotably supported and, when the recess 54 is pivoted to separate from the engagement pin 90, moves the unit part 3 in a direction of separating from the frame 100 by the pivoting.

### CROSS REFERENCE TO RELATED APPLICATION

The present application claims priority from Japanese Patent Application No. 2007-073956, which was filed on Mar. 22, 2007, the disclosure of which is herein incorporated by reference in its entirety.

### BACKGROUND OF THE INVENTION

1. Field of the Invention

The invention relates to an attaching/detaching structure of an electronic device, and more particularly, to an attaching/detaching structure of an electronic device suitable for a game medium lending apparatus that is disposed in a game arcade having a gaming machine such as a pachinko or slot machine (hereinafter, referred to as “gaming machine”) equipped therein and is provided between the gaming machines.

2. Description of Related Art

In general, in a game arcade such as pachinko hall, in order to offer convenience to a player, a game medium lending apparatus (electronic device) having a longitudinally elongated shape for lending a pachinko ball or coin (game medium) is provided between neighboring gaming machines, in an area (also referred to as “bank”) having several gaming machines equipped therein. Typically, the game medium lending apparatus has a frame that is fixedly mounted between each base and a unit part that is pulled out from the frame. The unit part, which is pulled out from the frame, receives a unit that processes a game value, for example a bill processing unit (also referred to as “bill value unit”) that processes bill as a game value, or a recording medium unit (card processing unit) that reads out recorded information recorded in a recording medium such as prepaid card or IC card having information about a game value recorded therein, or writes the information thereto. Further, the unit part receives a control unit that controls the driving of each unit received, for example, in addition to the game value processing unit.

The unit part has a front side exposed to a player. The exposed part is formed with an insertion slot into which the bill or card as a game value is inserted. When the bill or card is inserted into a predetermined insertion slot and a predetermined condition such as process of ascertaining whether it is true or not, authentication process and the like is cleared, a process of lending a game medium is carried out. In addition, the exposed part is provided with a numeric keypad operating part (numeric keypad operating unit) having a numeric keypad, with which a player can input the information about a game medium and the like.

The unit part as described above has a case for check and maintenance operations for each unit received therein and is structured in such a manner that it is attached and detached to and from the frame by an attaching/detaching structure as disclosed in a Japanese Patent Unexamined Publication No. 2005-46293. The attaching/detaching structure disclosed in the Japanese Patent Unexamined Publication No. 2005-46293 includes a pair of pivoting members provided to a unit part, an eccentric cam for rotating the pivoting members, a driving motor for rotating the eccentric cam and a link member that synchronizes and pivots the pivoting members. In addition, the frame is provided with a pair of engagement pins with which recesses formed at each of the pivoting members are engaged, and a pressing spring that forcibly biases the unit part forward. By driving the driving motor, the engagement between the pivoting members and the engagement pins is released, so that the unit part is thus pushed forward by the biasing force of the pressing spring.

### SUMMARY OF THE INVENTION

As described above, when detaching the unit part from the frame, the locked state of the attaching/detaching structure is released so as to easily perform the detaching operation, so that the unit part is moved forward.

However, the attaching/detaching structure disclosed in the Japanese Patent Unexamined Publication No. 2005-46293 requires the part (pressing spring) for biasing the unit part forward all the time. As a result, the number of parts is generally increased, so that the cost is higher.

The invention has been made to solve the above problem. An object of the invention is to provide an attaching/detaching structure of an electronic device which requires less number of parts and enables a unit part to be attachable/detachable to/from a frame in low costs.

In order to achieve the above object, there is provided an attaching/detaching structure of an electronic device including: a unit part that is attachable/detachable to/from a frame; and an engagement device that enables the unit part to be attachable/detachable to/from the frame and includes; an engagement pin disposed at one of the frame and the unit part; and an engagement member disposed at the other of the frame and the unit part, having a recess engaged with the engagement pin, wherein the engagement member is pivotably supported and, when the recess is pivoted to separate from the engagement pin, moves the unit part in a direction of separating from the frame by the pivoting.

In the above structure, when separating the unit part from the frame, the engagement member of the engagement device is pivoted, so that the engagement between the recess and the engagement pin is released. Furthermore, the engagement member is pivoted, thereby moving the unit part in a direction of separating from the frame. Due to this, it is not necessary to provide a special structure for moving the unit part in a direction of separating from the frame. As a result, the number of parts is decreased, so that the cost can be reduced.

### BRIEF DESCRIPTION OF THE DRAWINGS

Other and further objects, features and advantages of the invention will appear more fully from the following description taken in connection with the accompanying drawings in which:

FIG. 1 is a perspective view showing a structure of a game medium lending apparatus that is an example of an electronic device;

FIG. 2 is a block diagram showing constitutional elements of a frame and a game medium lending apparatus;

FIG. 3A shows an internal structure of a unit part;

FIG. 3B shows a part of a frame, seen from an attaching/detaching direction;

FIG. 4 shows a structure of an attaching/detaching device that is provided to a unit part;

FIG. 5A is a side view of an attaching/detaching device;

FIG. 5B is a front view of an attaching/detaching device;

FIG. 6A illustrates an action of an engagement member, showing a locked state between an engagement member and an engagement pin;

FIG. 6B illustrates an action of an engagement member, showing a state in which an engagement member is moved by an engagement pin;

FIG. 6C illustrates an action of an engagement member, showing a relation between an engagement pin and a recess after the engagement is moved;

FIG. 7 shows a state in which a unit part is moved in a direction of separating from a frame;

FIG. 8 shows a structure of a power transmission part constituting a driving unit of an attaching/detaching device (power transmission state);

FIG. 9 shows a structure of a power transmission part constituting a driving unit of an attaching/detaching device (power non-transmission state);

FIG. 10 shows a unit part, seen from a frame;

FIG. 11A illustrates an operation of a disengaging unit; and

FIG. 11B illustrates an operation of a disengaging unit.

### DESCRIPTION OF THE PREFERRED EMBODIMENTS

Hereinafter, an embodiment of an attaching/detaching structure of an electronic device according to the invention will be described. Meantime, as an electronic device, a game medium lending apparatus will be exemplified which can be provided between pachinko machines or pachi-slot machines disposed adjacent to each other. The game medium lending apparatus has a function of lending a game medium such as medal, pachinko ball and the like when cash or card (prepaid card, IC card and the like) is inserted.

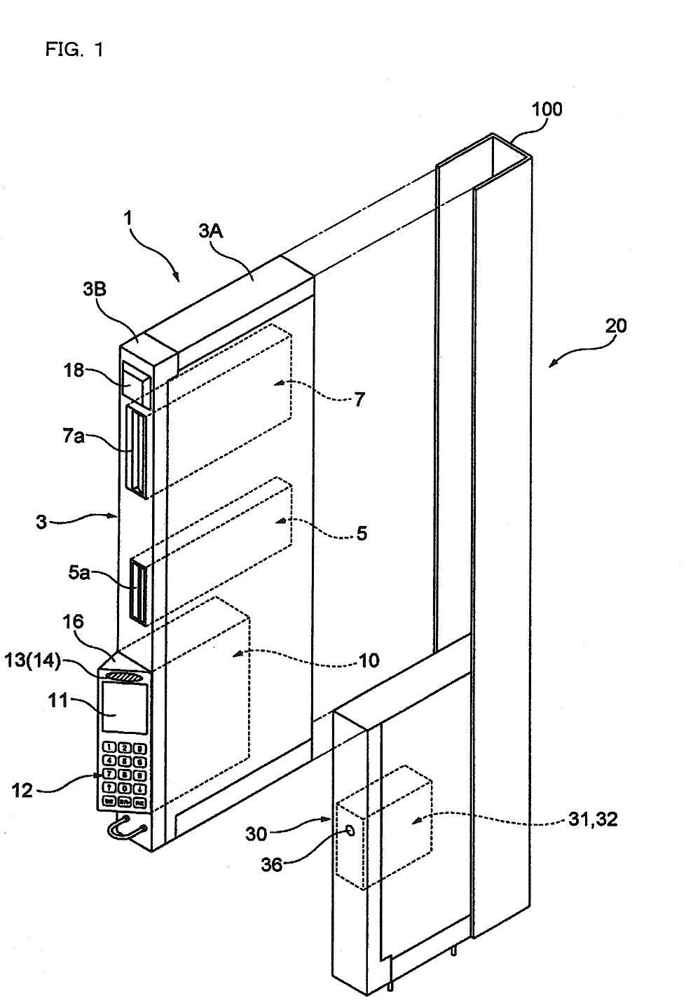

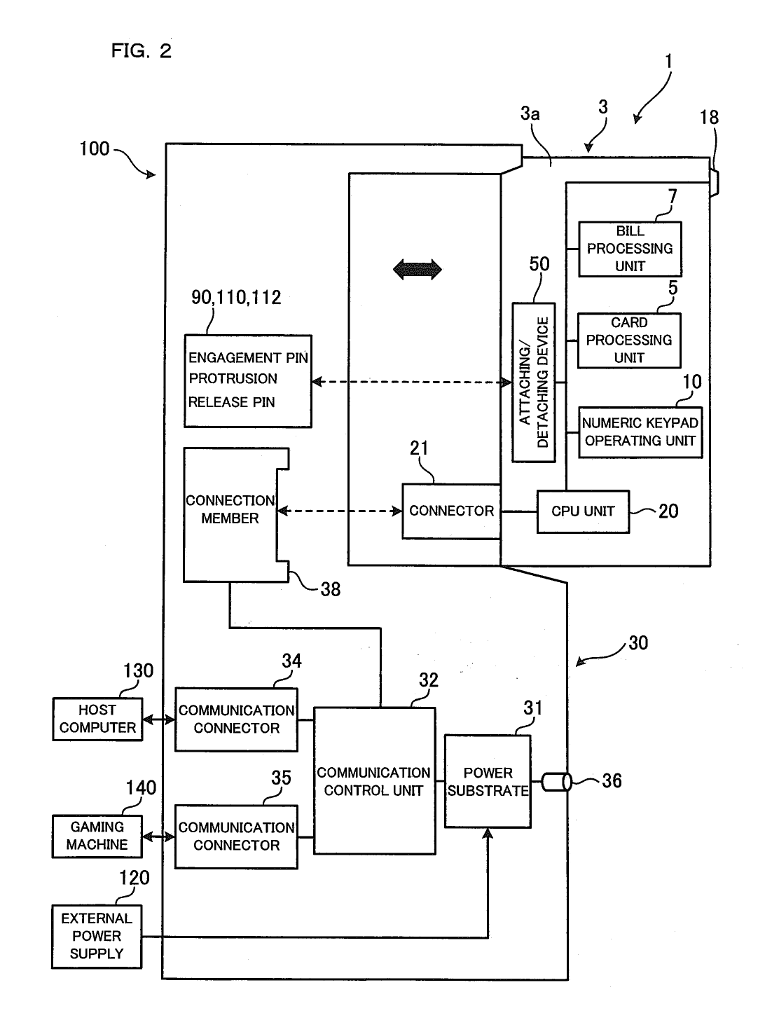

FIG. 1 shows a structure of a game medium lending apparatus that is attachable/detachable to/from a frame fixed between gaming machines which are not shown in the figure. FIG. 2 is a block diagram that shows constitutional elements of the frame and the game medium lending apparatus.

The game medium lending apparatus 1 of this embodiment has a box shape that is vertically long, and includes a unit part 3 that is attachable/detachable to/from a frame 100 (typically, a player cannot see it) having a section of a toppled “U” (“⊂”) shape and a power supply 30 that is disposed below the unit part 3 and has the same width as the unit part 3 and a vertically long box shape.

The game medium lending apparatus 1 allows the unit part 3, which is a constitutional element thereof, to be attachable/detachable to/from the frame 100 by an attaching/detaching device 50 which will be mentioned below. The power supply 30 is separated from the unit part 3 and is integrated to the frame 100.

The unit part 3 has a main body (casing) 3A, which is substantially rectangular parallelepiped and vertically long, in which a card processing unit 5, a bill processing unit 7 (these units constitute a paper sheet processing unit) and a numeric keypad operating unit 10. The units 5, 7, 10, which are frequently subject to the maintenance operation, are equipped in one unit part 3 that is detachable from the frame 100.

The card processing unit 5 has a card insertion slot 5a that is formed at a front panel 3B of the main body 3A in a longitudinal direction. For example, when a card (prepaid card, IC card and the like) having information about an amount of money is inserted into the slot, a reader writer provided therein is driven to perform the reading or re-writing operation of the information. In addition, the card processing unit is such structured that the card having the information about an amount of money re-written therein is returned or issued or the card is withdrawn when the amount of money becomes 0. A player can be lent the game medium such as pachinko ball or medal within a range of the amount recorded in the card.

The bill processing unit 7 has a bill insertion slot 7a that is formed at the front panel 3B of the main body 3A in a longitudinal direction. When bill is inserted in the slot, a sensor equipped therein checks whether the bill is genuine or not. Likewise the card, a player can be lent the game medium such as pachinko ball or medal within a range of the amount of money inserted. In the mean time, when all money is not consumed in a game, the information about the amount of money is recorded into the card which has been already received in a stock unit, and the issue thereof can be made in the card processing unit 5.

The numeric keypad operating unit 10 includes an image indicator 11 (includes a liquid crystal display), a numeric keypad 12, an infrared receiving element 13, and in the case may be, an imaging element 14 for authenticating a body. Meantime, in FIG. 1, the infrared receiving element 13 and the imaging element 14 are provided at the same position above the image indicator 11.

As shown in FIG. 1, the image indicator 11 and the numeric keypad 12 are mounted at a protrusion 16 having a surface inclined by 45° onto an exposed surface of the front panel 3B. By structuring so, the image indicator 11 is widened. In other words, as compared to a case where the image indicator 11 and the numeric keypad 12 are provided to an exposed surface of the front panel 3B, it is possible to dispose a liquid crystal display having a larger size of about 1.4 times. As a result, an image can be easily recognized and a player seating in a gaming machine disposed near to the game medium lending apparatus 1 can see the front, so that a visibility can be increased. In addition, the numeric keypad 12 can be also large-scaled, so that a press operation is facilitated.

The image indictor 11 has a function of displaying a variety of information about a game arcade, a two-dimensional barcode, an amount of money and the like, for example. The numeric keypad 12 is pressed, for example, when a player inputs a password of an IC card possessed, scrolls the variety of information displayed on the image indicator 11, or inputs the information about an amount of money to be used in a game. The infrared receiving element 13 is used, for example, when a manager of a game arcade drives the attaching/detaching device (release of a locked state) to detach the unit part 3 with an infrared remote control. The imaging element 14 is used to obtain the information for recognizing a body, for example, the information about whether a player plays a game in a gaming machine near to the game medium lending apparatus 1, and the like.

The unit part 3 may further include constitutional members in addition to the above units, and is provided with an indicating lamp 18 for notifying an abnormal situation, and the like.

The operations of the respective units are controlled by a CPU unit 20 that is provided in the unit part 3. A connector 21, which is mounted onto a back surface of the unit part 3, is connected to a connection member 38 mounted onto an inner surface of the frame 100, so that the CPU unit 20 is supplied with power from a power supply 30 and transmits/receives a variety of data to and from outside. In this case, as shown in FIG. 2, in this embodiment, the connector 21 and the connection member 38 are disposed and structured so that the connection between the connector 21 provided to the unit part 3 and the connection member 38 provided to the frame 100 is released when the unit part 3 is moved in a direction of separating from the frame 100.

The power supply 30 is provided therein with a power substrate 31 for controlling power supplied from an external power supply 120 so as to supply power to the card processing unit 5, the bill processing unit 7 and the numeric keypad operating unit 10 provided in the unit part 3 and a driving motor of an attaching/detaching device 50, and a communication control unit 32. The communication control unit 32 has a function of performing a conversion control of a communication way (serial/parallel conversion control) or a distribution control of a transmitting/receiving destination, and carries out a transmitting/receiving operation of various data with a host computer 130 and a neighboring gaming machine 140, through communication connectors 34, 35, respectively.

In addition, the power substrate (power supply unit) 31 has a function of serving as a charging unit enabling an external device such as portable terminal carried by a player to be charged. Furthermore, a predetermined charging terminal of an external device can be inserted to a charging jack 36 exposed from the front panel 3B.

The unit part 3 is retained in such a matter that it is attachable/detachable to/from the frame 100 through an attaching/detaching device 50. The attaching/detaching device 50 is structured in such a manner that an engagement device provided between the attaching/detaching device and the frame is simply released to pull out the unit part 3 with a hand.

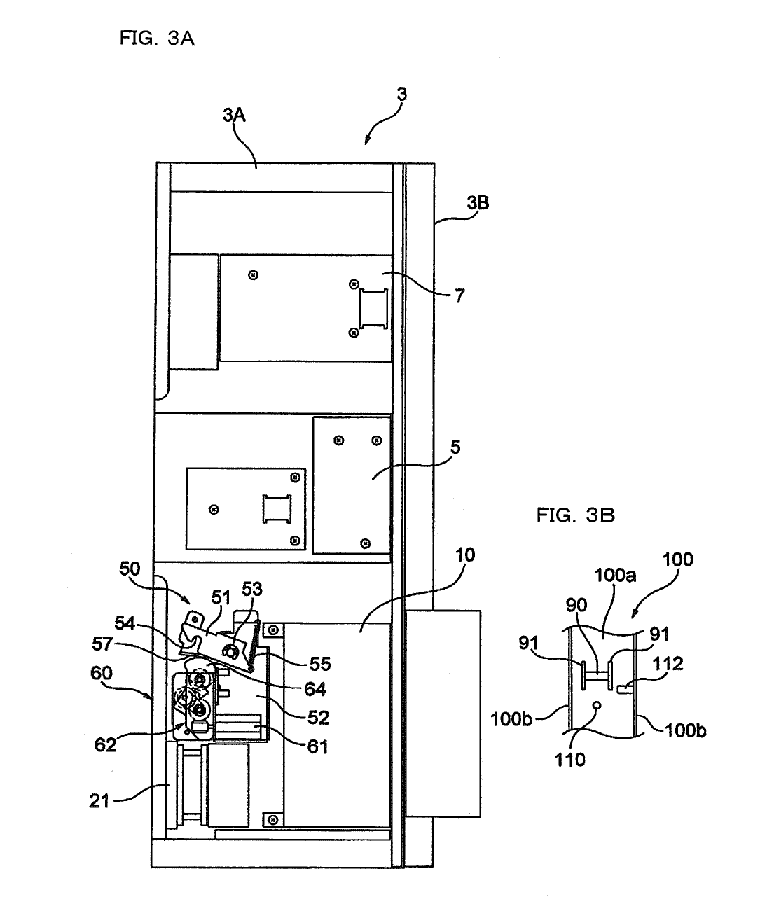

In the followings, the structure of the attaching/detaching device 50 will be described with reference to FIGS. 3A, 3B, 4, 5A and 5B.

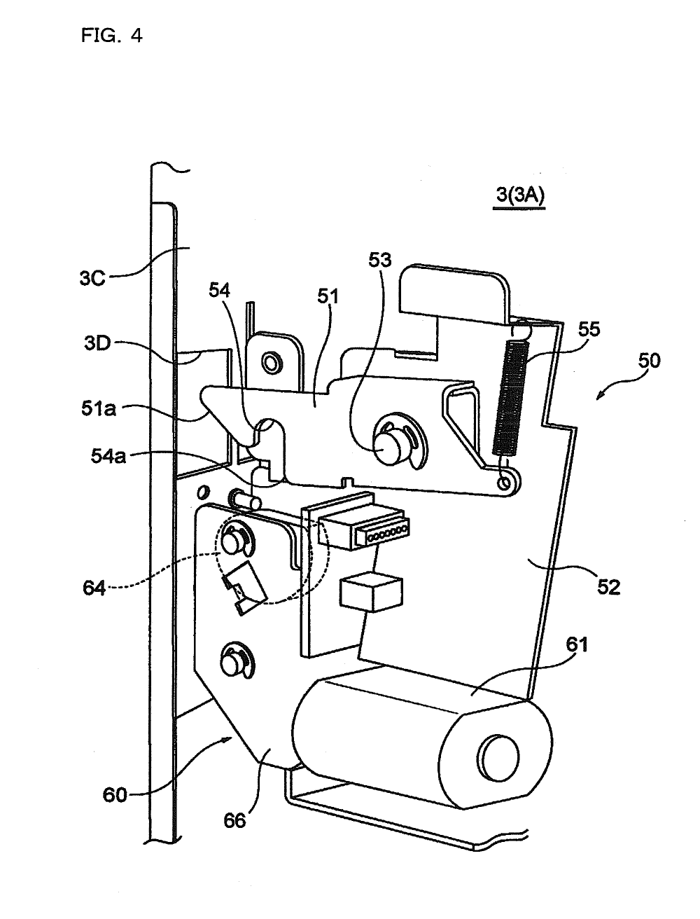

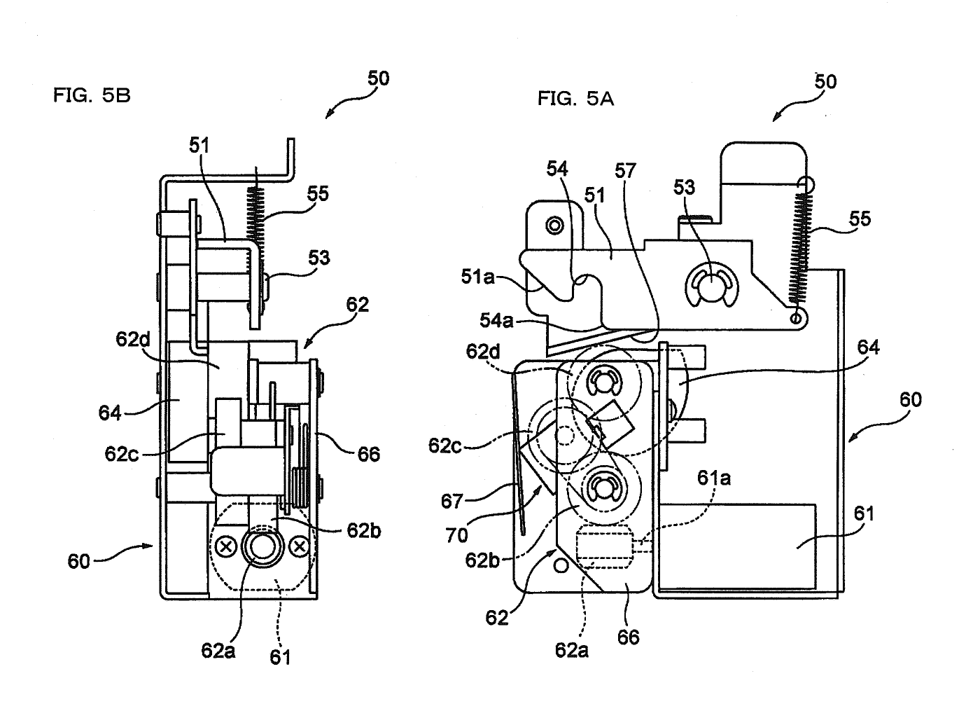

FIG. 3A shows an internal structure of the unit part, FIG. 3B shows a part of the frame, from an attaching/detaching direction, FIG. 4 shows a structure of the attaching/detaching device that is provided to the unit part, FIG. 5A is a side view of the attaching/detaching device, and FIG. 5B is a front view of the attaching/detaching device.

The attaching/detaching device 50 includes an engagement member 51, a driving unit 60 that drives the engagement member 51, and an engagement pin (lock pin) 90 that constitutes a locked state with the engagement member 51. In this case, the engagement member 51 is mounted onto the unit part 3 and the engagement pin 90 is mounted onto the frame 100. Both serve as an engagement device that locks the unit part 3. To be more specific, the engagement member 51 is pivotably supported on a plate 52 which is attached to an inner surface of the casing 3A of the unit part 3, with a support shaft 53 as a center, and the engagement pin 90 is provided between a pair of support walls 91 which are protruded from an inner surface 100a of the frame 100 having a section of a toppled “U” shape, in a manner that the supporting walls 91 are parallel to one another.

Due to this, as shown in FIG. 4, a back surface 3C (surface parallel to the front panel 3B) of the casing 3A, which is closely contacted to the inner surface 10a of the frame 100, is formed with a rectangular opening 3D. When mounting the unit part 3 onto the frame 100, the support walls 91 maintaining the engagement pin 90 are inserted into the opening 3D.

As described above, the unit part 3 receives the units 5, 7, which receives the card or bill, in a longitudinal direction so that an insertion slot for inserting the card or bill is extended in a vertical direction. Under such disposal state, the engagement member 51 is provided in the same direction as the units 5, 7, so that the game medium lending apparatus 1 can be made thin.

A leading end of the engagement member 51 is formed with a recess 54 that is extended in a vertical direction so as for the engagement pin 90 to engage with the recess. As the engagement member 51 is pivoted, the engagement pin 90 and the recess 54, which constitute the engagement device, are engaged, so that the unit part 3 is locked onto the frame 100 so that it cannot be removed.

In such a structure, when the recess 54 of the engagement member 51 is pivoted and separated from the engagement pin 90, the unit part 3 is moved in a direction of separating from the frame 100. Specifically, as a driving motor 61 provided to a driving unit 60, which will be described later, is rotated, the recess 54 is separated from the engagement pin 90. However, in the separation, the unit part 3 is moved only by the pivoting of the engagement member 51, without a spring or drive member.

In the followings, a structure for moving the unit part 3 will be described.

The engagement member 51 is provided with a tension spring (biasing member) 55 at one end (front panel side) about the support shaft 53. In the drawings, the tension spring 55 always biases the engagement member 51 in a counterclockwise direction about the support shaft 53. In addition, the other end (frame side) of the engagement member 51 is formed with an inclined portion 51a nearer to the leading end than the recess 54. When the unit part 3 is mounted onto the frame 100, the inclined portion 51a guides the engagement pin 90 into the recess 54. In other words, when the unit part 3 is mounted onto the frame 100, the engagement pin 90 collides with the inclined portion 51a, thereby pivoting the engagement member 51 in a clockwise direction against the biasing force of the tension spring 55 about the support shaft 53. As a result, when the engagement pin 90 is inserted into the recess 54, the both are engaged due to the biasing force of the tension spring 55.

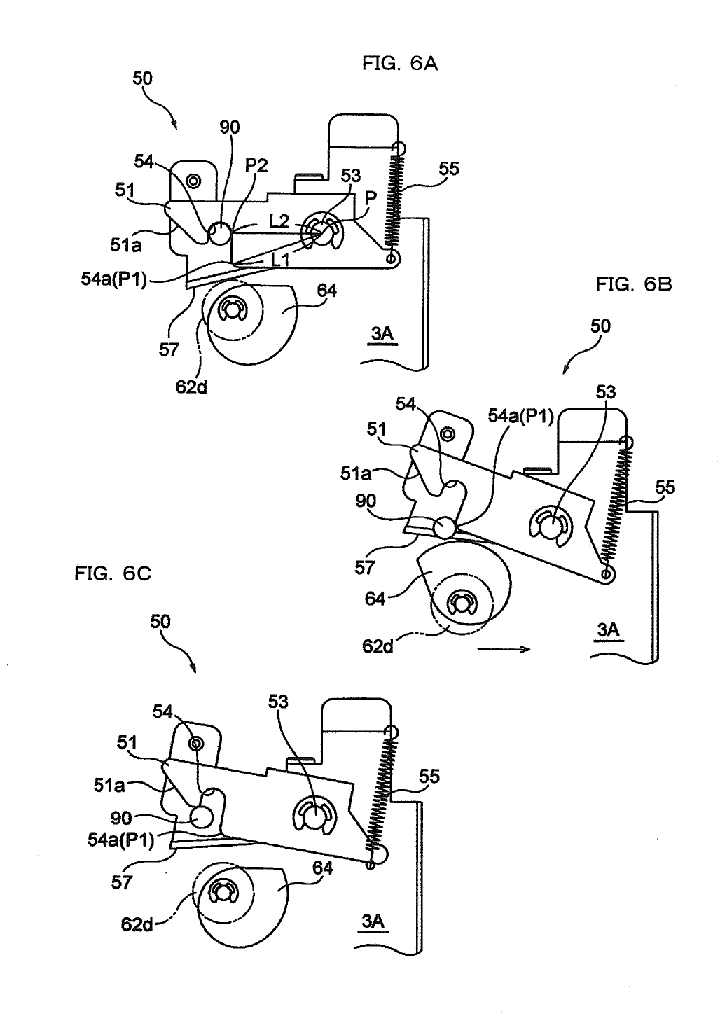

The engagement member 51 is formed with a contact portion 54a continuing on a contour defining the recess 54. The contact portion 54a is formed in such a manner that a part of the contour of the front panel side forming the recess 54 is extended downward. As shown in FIG. 6A, a position (indicated by a P1) of the contact portion 54a is formed at a location that is longer from the support shaft 53, as compared to an engaged portion (indicated by a P2) between the recess 54 and the engagement pin 90. In other words, assuming that a position of the support shaft 53 is “P,” the contact portion 54a of the engagement member 54 is set in such a manner that a distance L1 between the point P and the point P1 is longer than a distance L2 between the point P and the point P2.

Due to the above structure, when the engagement member 51 is pivoted about the support shaft 53, as shown in FIG. 6B, as the recess 54 is escaped from the engagement pin 90, the contact portion 54a pushes an outer circumferential surface of the engagement pin 90 and the engagement member 51 (the unit part 3 supporting the engagement member 51) is thus moved in an arrow direction (direction of separating from the frame 100) due to the resulting repulsive force. In the mean time, since the engagement member 51 pushes the engagement pin 90, the engagement pin 90 itself is about to be elastically deformed in a direction opposite to the arrow direction. However, since the engagement member 51 is pushed due to the restoring force, the contact portion 54a (point P1) of the engagement member 51 is maintained with being contacted to the outer circumferential surface of the engagement pin 90 and the unit part 3 is shifted to a detaching direction by a difference between the distances L1 and L2, as shown in FIG. 6B. Therefore, the recess 54 of the engagement member 51 cannot be engaged with the engagement pin 90. Like this, when the pivoting operation of the engagement member 51 is just ended, the engagement state between the engagement pin 90 and the recess 54 is released, the unit part 3 is moved in the detaching direction and the recess 54 of the engagement member 51 cannot be engaged with the engagement pin 90 (refer to FIG. 6C).

In the followings, a structure of the driving unit 60 will be described with reference to FIGS. 4, 5A and 5B.

The driving unit 60 includes a driving motor 61 and a power transmission part 62 that transmits the rotation driving force of the driving motor 61 to the engagement member 51.

In this embodiment, a power transmission part 62 includes a gear train, i.e., a worm gear 62a attached to an output shaft 61a of the driving motor 61 and first gear 62b, second gear 62c and third gear 62d that are sequentially engaged with the worm gear 62a. In this case, each of the gears 62b, 62c, 62d is rotatably supported on a maintaining frame 66 mounted onto the casing. To the third gear 62d, which is a final gear, is mounted with an eccentric cam 64 that is rotatable together with the third gear 62d. The eccentric cam 64 is structured to engage with a cam contact part 57 integrally formed below the engagement member 51. When the rotation driving force is transmitted through the gear train by the driving motor 61, the eccentric cam 64 is rotated, so that it is engaged to the cam contact part 57, as shown in FIG. 6B, from a state shown in FIG. 6A, and rotates the engagement member 51 about the support shaft 53.

In the mean time, in the structure that the engagement member 51 is pivoted using the eccentric cam 64 with the rotation driving force of the driving motor 61, when the unit part 3 is detached from the frame 100 and the maintenance operation is performed for each unit, if the eccentric cam 64 is accidentally rotated, the power is transmitted to the driving motor, thereby applying unnecessary load to the driving motor 61 and causing inconvenience to the peripheral parts. Due to this, the power transmission part 62 is provided with a release device 70 that releases the power transmission to the eccentric cam 64 from the driving motor 61.

Since the power transmission part 62 includes the gear train, the release device 70 is structured in such a manner that it maintains/releases the engaged state between one gear and the other gears. To be more specific, the second gear 62c of the gear train is displaceably supported on the maintaining frame 66 and is biased and engaged to the first gear 62b and the third gear 62d by a leaf spring (biasing member) 67.

The leaf spring 67 is disposed along the back surface 3C that is closely contacted to the inner surface 10a of the frame 100 of the casing 3A and is pressed by a protrusion 110 (refer to FIG. 3B) that is protruded from the inner surface 100a of the frame in the detaching direction. In other words, when the unit part 3 is mounted onto the frame 100, the back surface 3B of the casing 3A of the unit part 3 is closely contacted to the inner surface 100a of the frame 100. At this time, however, the protrusion 110 presses the leaf spring 67 and the second gear 62c is thus engaged to the first gear 62b and the third gear 63d by the biasing force, so that the power transmission state is maintained. In the mean time, when the unit part 3 is moved in the direction of separating from the frame 100, the pressing of the protrusion 110 to the leaf spring 67 is released and the second gear 62c is thus disengaged with the first gear 62b and the third gear 63d, so that the power transmission state is released.

Like this, when the unit part 3 is detached from the frame 100, the power transmission state of the power transmission part 62 is automatically released.

Furthermore, in this embodiment, the attaching/detaching device 50 is provided with a disengaging unit 80 that releases the engagement between the eccentric cam 64 and the engagement member 51 when the unit part 3 is mounted onto the frame 100. In the attaching/detaching device 50, when the unit part 3 is detached from the frame 100, the engagement member 51 is pivoted in the direction of separating from the engagement pin 90 by the eccentric cam 64, as shown in FIG. 6B. In such a state, when a maintenance operation is over and thus the unit part 3 is mounted onto the frame, there may occur a situation in which the engagement member 51 under released state is not engaged with the engagement pin 90 and thus an unlocked state is caused (i.e., a locked state is not caused even though the unit part 3 is mounted onto the frame). Alternatively, as described above, since the load is not applied to the eccentric cam 64 due to the release device 70, the eccentric cam 64 may be engaged with the engagement member 51, thereby moving the engagement pin 90 in a release direction due to check and maintenance operations of the unit part 3.

Due to this, in this embodiment, when the unit part 3 is mounted onto the frame 100, the unlocked state is certainly prevented by the disengaging unit 80.

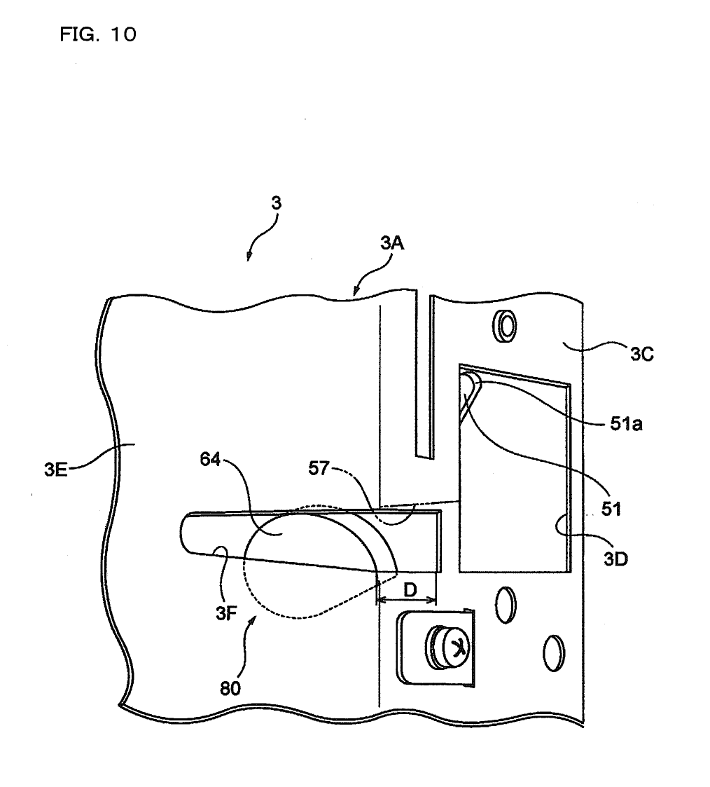

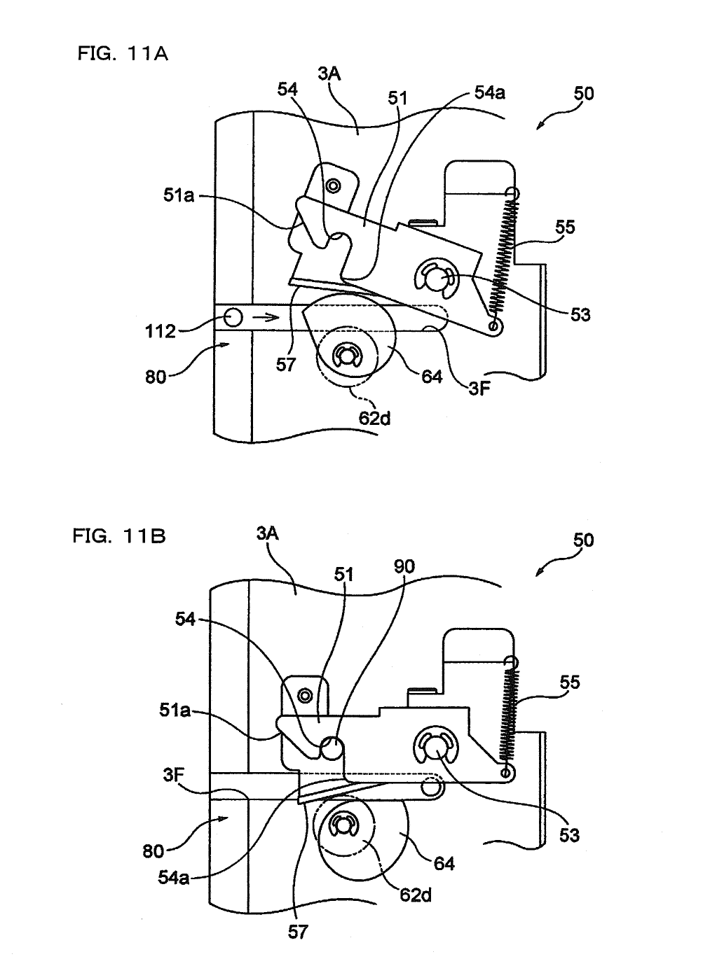

In the followings, a structure of the disengaging unit 80 will be described with reference to FIGS. 3B, 10, 11A and 11B. Meantime, FIG. 10 shows the unit part 3, seen from the frame 100, and FIGS. 11A and 11B illustrates an operation of the disengaging unit 80.

As shown in FIG. 10, the casing 3A constituting the unit part 3 is formed with a pin guide opening 3F from the back surface 3C to a side surface 3E. The pin guide opening 3F is formed to be identical to the position (refer to FIG. 6B) at which the eccentric cam 64 engaged with the engagement member 51 pivots the engagement member 51. In other words, the engaged state of the eccentric cam 64 and the engagement member 51 is set to be exposed through the pin guide opening 3F, as shown in FIG. 10.

In the mean time, as shown in FIG. 3B, a side 100b of the frame 100 having a toppled “U” shape is formed with a release pin 112 that is protruded in a direction perpendicular to the attaching/detaching direction. A height of the release pin 112 is somewhat less than a depth D of the pin guide opening 3F formed to the back surface 3C, as shown in FIG. 10.

According to the disengaging unit 80, the engaged state of the eccentric cam 64 and the engagement member 51 is released by the release pin 112 when the unit part 3 is mounted onto the frame 100, and the engagement pin 90 is certainly inserted into the recess of the engagement member 51 at the engaged state, so that the locked state is secured.

In the followings, the actions and effects of the game medium lending apparatus structured as described above will be described.

First, the unit part 3 of the game medium lending apparatus 1 is mounted (locked) onto the frame 100. At this time, as shown in FIG. 6A, the eccentric cam 64 and the engagement member 51 are under disengaged state, and the recess 54 of the engagement member 51 is engaged and locked with the engagement pin 90 of the frame 100.

In detaching the unit part 3, when a manager of a game arcade illuminates the light to the infrared receiving element 13 with a remote control, for example, the CPU unit 20 rotates the driving motor 61 of the attaching/detaching device 50. A rotation driving amount of the driving motor 61 is controlled within a predetermined range. The rotation driving force of the driving motor 61 is transmitted to the eccentric cam 64 through the power transmission part 62 including the gear train, thereby rotating the eccentric cam 64 in the counterclockwise direction in FIG. 6A. Thereby, the eccentric cam 64 is engaged with the cam contact portion 57 of the engagement member 51 and the engagement member 51 is rotated in the clockwise direction against the biasing force of the tension spring 55 about the support shaft 53.

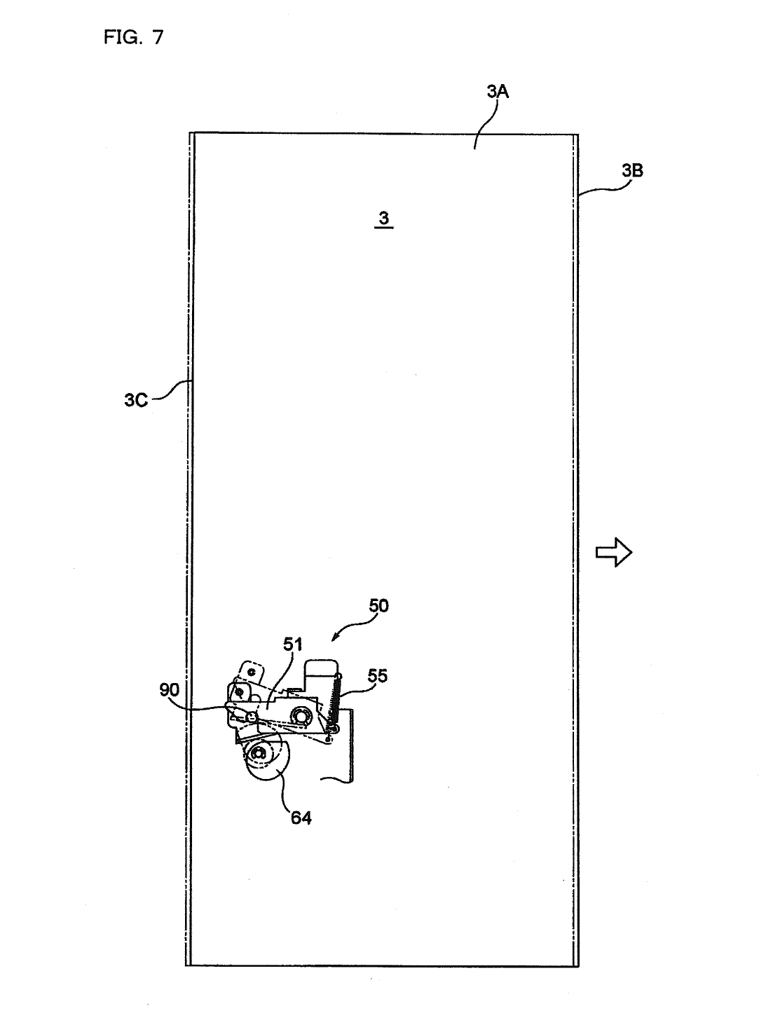

Like this, when the engagement member 51 is pivoted about the support shaft 53, as the recess 54 is escaped from the engagement pin 90, the contact portion 54a pushes an outer circumferential surface of the engagement pin 90 and the engagement member 51 (the unit part 3 supporting the engagement member 51) is thus moved in the direction of separating from the frame 100 due to the resulting repulsive force (i.e., the engagement member is moved from the double-dotted line of FIG. 7, as shown in the solid line). In other words, when the pivoting operation of the engagement member 51 is just ended, the engagement state between the engagement pin 90 and the recess 54 is released and the unit part 3 is moved in the detaching direction. Accordingly, since it is not necessary to provide a special structure for moving the unit part 3 in the direction of separating from the frame 100, the number of parts is decreased and the cost can be thus reduced.

In addition, as shown in FIG. 2, when the unit part 3 is moved in the direction of separating from the frame 100, the connector 21 provided to the unit part 3 is escaped from the connection member 38 of the frame 100 (i.e., connection between the connector 21 and the connection member 38 is released). Accordingly, when the unit part 3 is detached from the frame 100, an operation for releasing the connection is not required and the unit part 3 can be easily pulled out from the frame 100. In addition, when detaching the unit part 3 from the frame 100, the connection between the connector 21 and the connection member 38 is released, so that the power supply to the unit part 3 is stopped. Therefore, it is not necessary to stop the driving motor 61 of the unit part 3 detached from the frame 100, so that the driving of the driving motor 61 is easily controlled.

The unit part 3 is pulled out from the frame 100 and the check and maintenance operations are then carried out for the various units received in the unit part 3. At this time, the power transmission state for the power transmission part 62 between the driving motor 61 and the eccentric cam 64 is released by the release device 70. Accordingly, even when the eccentric cam 64 is accidentally rotated while performing the maintenance operation for the respective units, the power is not transmitted to the driving motor 61, the unnecessary load is not applied to the driving motor 61 and inconvenience is not caused to the peripheral parts.

Then, when the unit part 3 is again pulled into the frame 100 so as to mount the unit part 3 onto the frame 100, the release pin 112 formed at the frame 100, which constitutes the disengaging unit 80, is moved in the pin guide opening 3F formed at the unit part 3 (refer to FIG. 11A). At this time, even when the eccentric cam 64 is engaged with the engagement member 51, the release pin 112 contacts the eccentric cam 64, thereby rotating the eccentric cam 64 in the clockwise direction and thus releasing the engaged state. In other words, since the eccentric cam 64 is under load-free state (free rotatable state) due to the release device 70, even if the eccentric cam 64 is engaged with the engagement member 51, the eccentric cam 64 is rotated by the release pin 112 and the engagement member 51 is certainly returned to the initial position (position at which the engagement pin 90 can enter the recess 54 of the engagement member 51; refer to FIG. 4) by the tension of the tension spring 55.

When the unit part 3 is further inserted, the engagement pin 90 collides with the inclined portion 51a, thereby rotating the engagement member 51 in the clockwise direction against the biasing force of the tension spring 55 about the support shaft 53. Finally, as shown in FIG. 11B, when the engagement pin 90 enters the recess 54, the both are engaged (locked) by the biasing force of the tension spring 55. In other words, since the eccentric cam 64 is positively disengaged with the engagement member 51 by the disengaging unit 80, when the unit part 3 is mounted onto the frame 100, it is locked to the engagement pin 90, so that an unlocked state is certainly prevented.

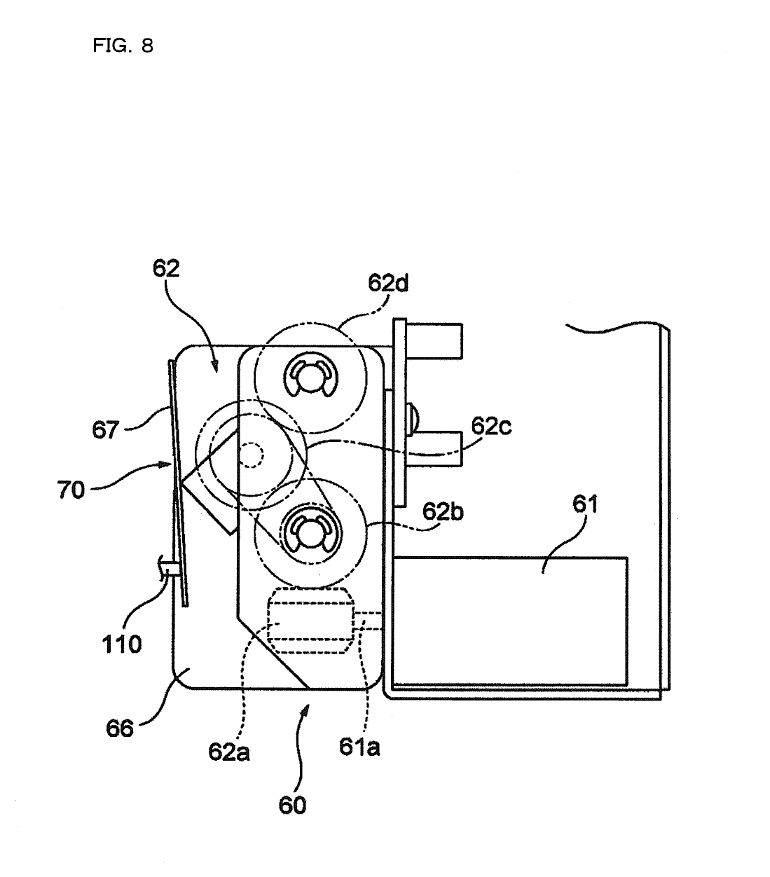

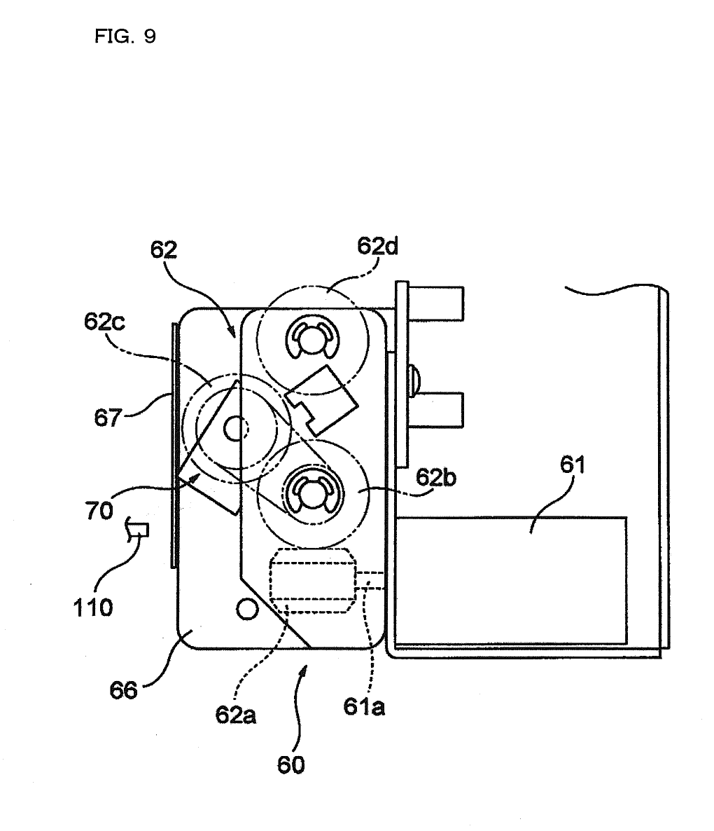

In addition, when the unit part 3 is mounted onto the frame 100, the protrusion 110 (refer to FIG. 3B) constituting the release device 70 presses the leaf spring 67, the second gear 62c is engaged with the first gear 62b and the third gear 63d by the biasing force thereof and the power transmission part 62 is maintained under power transmission state (FIG. 9→FIG. 8). In addition, the connector 21 provided to the unit part 3 is connected to the connection member 38 of the frame 100 as it is, and an inconvenience of the connection is not caused.

Although the invention has been described with reference to the preferred embodiment, the invention is not limited thereto and can be variously modified.

Since the invention is characterized by the attaching/detaching device 50, the other constitutional elements can be appropriately modified without being limited to the above embodiment. In addition, in the attaching/detaching device 50, the power transmission manner between the driving motor 61 and the eccentric cam 64 is not limited to the gear train. Furthermore, the release device 70 may be correspondingly modified. In the mean time, the release device 70 may be arbitrarily structured as long as the power transmission state is released in the power transmission part when the unit part 3 is detached from the frame 100.

In addition, in the attaching/detaching device 50, the engagement member 51 or driving unit 60 may be mounted onto the frame.

The invention can be applied to various electronic devices, in addition to the game medium lending apparatus. For example, the invention can be applied to a variety of electronic devices having a unit structure that is attached and detached to and from a frame, such as a CD-ROM drive unit mounted in a PC.

In the above descriptions, the invention has been described for the characteristic thereof so as to easily understand the invention. However, the invention is not limited to the embodiment and can be applied to the other embodiments, and the applicable scope thereof is construed as broad as possible. In addition, the terms and phrases used in the specification are used to correctly describe the invention, not to limit the invention. Furthermore, it can be easily understood by one skilled in that art that the other structures, systems and methods to be included in the invention can be made without departing the scope and spirit of the invention described in the specification. Accordingly, the appended claims should be construed to include the equivalent structure within a range without departing the technical spirit of the invention. Further, the abstract is provided so that an intellectual property office and a general public institution or one skilled in the art who is not familiar with patent and legal or professional terminology can quickly analyze the technical features and essences of the invention through a simple investigation. Accordingly, the abstract is not intended to limit the scope of the invention that should be evaluated by the claims. In addition, it is preferred to sufficiently refer to the documents that have been already disclosed, so as to fully understand the objects and effects of the invention.

The above descriptions include a process that is executed on a computer or computer network. The above descriptions and expressions have been provided so that the one skilled in the art can understand the invention most effectively. In the specification, the respective steps used to induce one result or blocks having a predetermined processing function should be understood as a process having no self-contradiction. In addition, the electrical or magnetic signal is transmitted/received and written in the respective steps or blocks. Although the processes in the respective steps or blocks embody the signal as a bit, value, symbol character, term, number and the like, it should be noted that these have been used for the convenience of descriptions. Further, although the processes in the respective steps or blocks have been often described as an expression common to a human action, the process described in the specification is executed by a variety of devices in principle. In addition, the other structures necessary for the respective steps or blocks are apparent from the above descriptions.

While this invention has been described in conjunction with the specific embodiments outlined above, it is evident that many alternatives, modifications and variations will be apparent to those skilled in the art. Accordingly, the preferred embodiments of the invention as set forth above are intended to be illustrative, not limiting. Various changes may be made without departing from the spirit and scope of the invention as defined in the following claims.

What is claimed is:

1. An attaching/detaching structure of an electronic device comprising:
a unit part that is attachable/detachable to/from a frame; and
an engagement device that enables the unit part to be attachable/detatchable to/from the frame and comprises an engagement pin disposed at one of the frame and the unit part, and an engagement member disposed at the other of the frame and the unit part, having a recess engaged with the engagement pin,
wherein the engagement member is pivotably supported and, when the recess is pivoted to separate from the engagement pin, moves the unit part in a direction of separating from the frame by the pivoting.

2. The attaching/detaching structure according to claim 1, further comprising:
a biasing member that biases the recess of the engagement member in a direction of engaging with the engaging pin;
an inclined portion that is formed at the engagement member and guides the engagement pin into the recess when the unit part is mounted onto the frame; and
a contact portion that is formed to continue on the recess of the engagement member and contacts the engagement pin, as it is, to move the unit part in a separating direction, after the engagement between the engagement pin and the recess is released due to the pivoting of the engagement member.

3. The attaching/detaching structure according to claim 1, wherein the engagement device comprises an eccentric cam that contacts the engagement member and a driving motor that rotates the eccentric cam.

4. The attaching/detaching structure according to claim 1, wherein the unit part receives a paper sheet processing unit in a longitudinal direction so that an insertion slot for inserting a paper sheet is extended in a vertical direction, the paper sheet processing unit accommodating the paper sheet, and
wherein the engagement member is provided in the same direction as the paper sheet processing unit.

5. The attaching/detaching structure according to claim 1, wherein the unit part includes a connector and the frame includes a connection member to which the connector of the unit part is connected, and
wherein as the unit part is moved in a direction of separating from the frame, the connection between the connector and the connection member is released.

6. The attaching/detaching structure according to claim 5, wherein the frame includes a power supply that supplies power to the unit part and power supply is carried out through the connector.

7. The attaching/detaching structure according to claim 6, wherein the power supply includes a charging jack into which a charging terminal of an external device is inserted, and a power supply unit that supplies the power to the external device through the charging jack.
